(19) United States
(12) Patent Application Publication
(10) Pub. No.: US 2010/0005652 A1
(43) Pub. Date: Jan. 14, 2010

(54) Method of manufacturing a wiring substrate, method of manufacturing a tape package and method of manufacturing a display device

(75) Inventors: Dong-Han Kim, Osan-si (KR); Kyoung-Sei Choi, Yongin-si (KR); Kyong-Soon Cho, Goyang-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/458,430

(22) Filed: Jul. 13, 2009

(30) Foreign Application Priority Data
Jul. 14, 2008 (KR) 10-2008-0068170

(51) Int. Cl. H05K 3/20; H01S 4/00

(52) U.S. Cl. 29/831; 29/592.1; 29/832

(57) ABSTRACT

Disclosed is a method of manufacturing a wiring substrate, a tape package using the wiring substrate, and a display device using the wiring substrate. In a method of manufacturing a wiring substrate, a screen may be disposed on a base plate, the screen having openings for forming wirings. A conductive paste may be coated in the openings of the screen. A substrate may be on the screen, the conductive paste being coated in the openings of the screen. The conductive paste may be hardened to be adhered to the substrate. The base plate and the screen may be removed from the substrate to form wirings on the substrate. Because the wirings may be formed using a glass substrate having heat-resisting properties by simplified processes, thermal deflections of the substrate and dimension variations in manufacturing processes may be reduced or minimized.

This application claims priority under 35 U.S.C. §119 to Korean Patent Application No. 2008-68170, filed on Jul. 14, 2008 in the Korean Intellectual Property Office (KIPO), the entire contents of which are herein incorporated by reference.

### BACKGROUND

1. Field

Example embodiments relate to a method of manufacturing a wiring substrate, a method of manufacturing a tape package, and a method of manufacturing a display device. More particularly, example embodiments relate to a method of manufacturing a wiring substrate where a semiconductor chip for driving a display panel is mounted, a method of manufacturing a tape package including the wiring substrate, and a method of manufacturing a display device including the same.

2. Description of the Related Art

Generally, semiconductor devices are manufactured using various processes which may include a fabrication process, an electrical die sorting (EDS) process, a packaging process, and a sorting process. The fabrication process may form electric circuits including electric elements on a semiconductor substrate, for example, a silicon wafer. An electrical die sorting (EDS) process may be used for inspecting electrical properties of chips formed by the fabrication process. The packaging process may be used for sealing the chips with a resin, for example, an epoxy.

Through the packaging process, a semiconductor device, for example, a semiconductor chip may be electrically connected to a mounting substrate, and the semiconductor chip may be sealed to be protected from the outside. The semiconductor package including the semiconductor chip mounted on the mounting substrate dissipates heat from the semiconductor chip outside through cooling functions thereof. For example, methods of electrically connecting the semiconductor chip to the mounting substrate may include a wire bonding process, a solder bonding process, and a tape automated bonding (TAB) process.

In the conventional art, the manufacturing industry for tape packages, which may be used as driver integrated circuit (IC) components for flat-panel displays (FPDs), owes its growth to the development of the manufacturing industry for FPDs, for example, liquid crystal displays (LCDs). A tape package may be a semiconductor package using a tape substrate. The tape package may be classified as either a tape carrier package (TCP) or a chip-on-film (COF) package.

Input/output (I/O) wiring patterns may be formed on the tape substrate and may be used as external connection terminals in the TAB process. The I/O wiring patterns may be directly adhered to a printed circuit board (PCB) or a display panel to manufacture the tape package.

In a conventional method of forming the I/O wiring pattern of the tape substrate, a metal thin film may be adhered to a surface of the base film of the tape substrate by an electrodeposition or thermocompression process. A photolithography process and an etch process may be performed on the metal thin film to form the wiring pattern.

Accordingly, in order to form the wiring pattern, complicated processes including a photolithography process and an etch process are required. Further, the base film may be shrunk or expanded due to attraction forces, thermal changes and humidity changes for alignments in the manufacturing processes, thereby increasing tolerance variations. Moreover, an upper portion of the wiring may be over-etched by a flow of an etching solution in a conventional etch process, such that the wiring has a trapezoidal shape with a progressively reduced width toward the top.

### SUMMARY

Example embodiments provide a method of manufacturing a wiring substrate by simplified processes with reduced or minimized tolerance variations.

Example embodiments provide a method of manufacturing a tape package including the wiring substrate.

Example embodiments provide a method of manufacturing a display device including the wiring substrate.

In accordance with example embodiments, a method of manufacturing a wiring substrate may include placing a screen on a base plate, the screen having openings for forming wirings, coating a conductive paste in the openings of the screen, placing a substrate on the screen, hardening the conductive paste to adhere the conductive paste to the substrate, and removing the base plate and the screen from the substrate.

According to example embodiments, in a method of manufacturing a wiring substrate, a screen may be disposed on a base plate and the screen may have openings for forming wirings. A conductive paste may be coated in the openings of the screen. A substrate may be disposed on the screen and the conductive paste may be coated in the openings of the screen. The conductive paste may be hardened to be adhered to the substrate. The base plate and the screen may be removed from the substrate.

In an example embodiment, the method may further include forming an adhesive layer on the conductive paste before disposing the substrate on the screen.

In example embodiments, the adhesive layer may include chromium (Cr). The adhesive layer may have a root-mean-square (RMS) roughness greater than a RMS roughness of the conductive paste.

In example embodiments, hardening the conductive paste may include heating the base plate.

In example embodiments, the base plate may include a glass substrate, and hardening the conductive paste may include irradiating light onto the glass substrate such that the conductive paste is hardened to be adhered to the substrate.

In example embodiments, the substrate may include polyimide.

In example embodiments, the base plate may be a glass substrate.

In example embodiments, the screen may include glass or silicon.

According example embodiments, in a method of manufacturing a tape package, a screen may be disposed on a base plate and the screen may have openings for forming wirings. A conductive paste may be coated in the openings of the screen. A substrate may be disposed on the screen, the conductive paste may be coated in the openings of the screen. The conductive paste may be hardened to be adhered to the substrate. The base plate and the screen may be removed from the substrate to form a wiring substrate including wirings. A semiconductor chip may be mounted on the wiring substrate.

In example embodiments, the method may further include forming an adhesive layer on the conductive paste before disposing the substrate on the screen.

In example embodiments, the adhesive layer may include chromium (Cr). The adhesive layer may have a root-mean-square (RMS) roughness greater than a RMS roughness of the conductive paste.

In example embodiments, mounting the semiconductor chip on the substrate may include adhering terminal pads of the semiconductor chip to connection end portions of the wirings via bumps interposing therebetween.

In example embodiments, the method may further include injecting a plastic resin to a bonded region of the wiring substrate and the semiconductor chip.

In example embodiments, the semiconductor chip may include driving circuits for driving a display panel.

According to example embodiments, in a method of manufacturing a display device, a screen may be disposed on a base plate and the screen may have openings for forming wirings. A conductive paste may be coated in the openings of the screen. A substrate may be disposed on the screen, the conductive paste may be coated in the openings of the screen. The conductive paste may be hardened to be adhered to the substrate. The base plate and the screen may be removed from the substrate to form a wiring substrate including wirings. A semiconductor chip may be mounted on the wiring substrate to form a tape package. A first end portion of the tape package may be combined with a PCB. A second end portion of the tape package may be combined with a display panel.

In example embodiments, combining the first end portion of the tape package with the PCB may include electrically connecting input wirings of the wirings of the tape package to the PCB.

In example embodiments, combining the second end portion of the tape package with the display panel may include electrically connecting output wirings of the wirings of the tape package to the display panel.

According to example embodiments, the conductive paste may be formed on the base plate with low thermal deflection, for example, the glass substrate, to have a required pattern by a screen printing process. After the substrate may be disposed on the base plate, the conductive paste having the required pattern may be adhered to the substrate. Then, the base plate may be removed to form the wirings having a required pattern.

Accordingly, the wirings may be formed on the substrate without performing an exposure process and an etching process. Because the wirings are formed using the glass substrate having heat-resisting properties by simplified processes, thermal deflections of the substrate and dimension variations in manufacturing processes may be reduced or minimized.

### BRIEF DESCRIPTION OF THE DRAWINGS

Example embodiments will be more clearly understood from the following detailed description taken in conjunction with the accompanying drawings.

FIGS. 1A to 1E are cross-sectional views illustrating a method of manufacturing a wiring substrate in accordance with example embodiments.

FIG. 2 is a plan view illustrating the wiring substrate in FIG. 1E.

FIG. 3 is a plan view illustrating a tape package including a semiconductor chip mounted on the wiring substrate in FIG. 2.

FIG. 4 is a plan view illustrating a display device including the tape package in FIG. 3.

### DETAILED DESCRIPTION OF EXAMPLE EMBODIMENTS

Example embodiments will be described more fully hereinafter with reference to the accompanying drawings, in which example embodiments are shown. The present invention may, however, be embodied in many different forms and should not be construed as limited to example embodiments set forth herein. Rather, example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers that may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

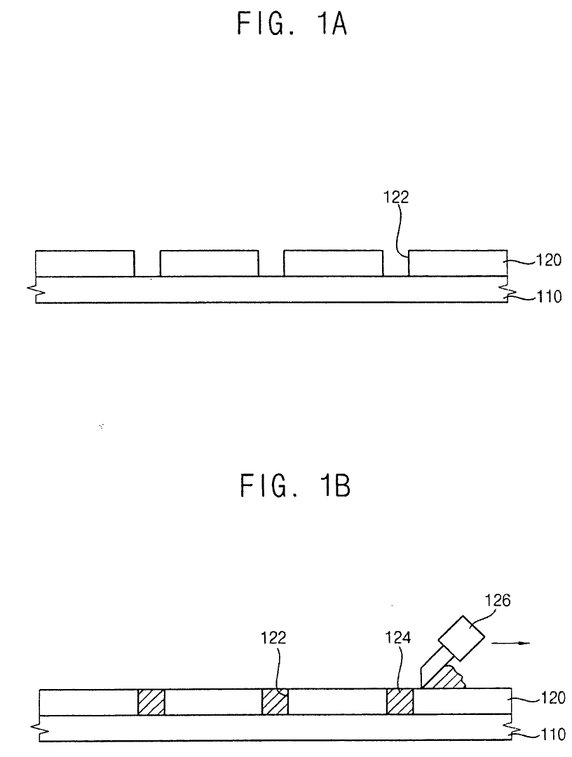

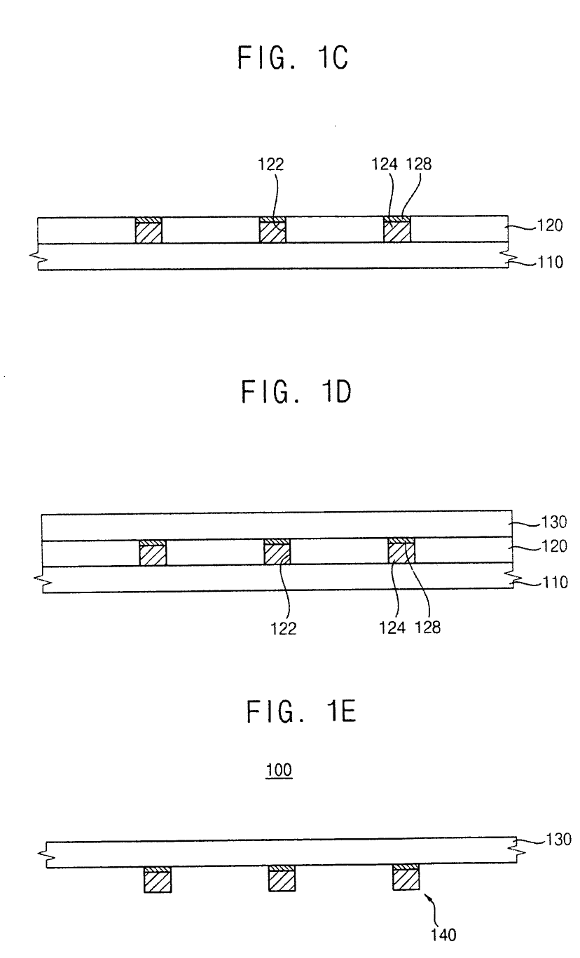

FIGS. 1A to 1E are cross-sectional views illustrating a method of manufacturing a wiring substrate in accordance with example embodiments.

Referring to FIG. 1A, a screen 120 may be disposed on a base plate 110. A plurality of openings 122 for forming wirings may be formed in the screen 120. The openings for wirings may be determined according to positions and dimensions of the wirings to be formed by a following process.

In example embodiments, the base plate 110 may be a glass substrate. The screen 120 may include glass, silicon, and/or a metal, for example, steel.

Referring to FIG. 1B, a conductive paste 124 may be coated on the screen 120. In accordance with example embodiments, the conductive paste 124 may be a semisolid conductive paste 124. The conductive paste 124 may be coated on the screen 120 and a scraper 126 may be used to fill in the openings 122 with the conductive paste 124. For example, the scraper 126 may be moved to push and press the conductive paste 124 into the openings 122 to form wirings. Accordingly, the conductive paste 124 may fill the openings 122.

In example embodiments, the conductive paste 124 may include copper (Cu), gold (Au), tin (Sn), lead (Pb), silver (Ag), and/or nickel (Ni).

Referring to FIG. 1C, an adhesive layer 128 may be formed on the conductive paste 124 in the openings 122.

For example, the adhesive layer 128 may include chromium (Cr). The adhesive layer 128 may have a root-mean-square (RMS) roughness greater than a RMS roughness of the conductive paste 124. The adhesive layer 128 having a relative greater roughness may increase adhesive strength with a substrate to be adhered by a following process.

In example embodiments, the process of forming the adhesive layer 128 may be omitted for simplicity.

Referring to FIG. 1D, a substrate 130 may be disposed on the screen 120 including the conductive paste 124 coated therein and the conductive paste 124 may be hardened to be adhered to the substrate 130.

The substrate 130 may have an adhered surface facing the screen 120. The substrate 130 may be disposed on the screen 120 and the conductive paste 124 may be adhered to the substrate 130.

For example, the substrate 130 may include an organic material, for example, a polyimide and/or an epoxy resin. The substrate 130 may be a flexible organic film.

In example embodiments, a thermal treatment may be performed on the screen 120 including the conductive paste 124 such that the conductive paste 124 is adhered to the substrate 130. For example, the base plate 110 may be thermally heated to a preliminary temperature, for example, a predetermined or preset temperature, where the conductive paste 124 may be hardened to be adhered to the substrate 130.

Example embodiments also provide for an irradiation treatment to adhere the conductive paste 124 to the substrate 130. For example, the base plate 110 may include a glass substrate and light may be irradiated onto the base plate 110 such that the conductive paste 124 is hardened. The light irradiating the base plate 110 may harden the conductive paste 124 to be adhered to the substrate 130. For example, ultraviolet light may be irradiated onto the base plate 110. The adhesive layer 128 having a relatively rough surface may be formed on the conductive paste 124 to increase an adhesive strength with the substrate 130.

Referring to FIG. 1E, the base plate 110 and the screen 120 may be removed to form a wiring substrate 100. A plurality of wirings 140 may be formed from the conductive paste 124 on the substrate 130 to have a required wiring pattern. Accordingly, the wiring substrate 100 may include the substrate 130 and a plurality of the wirings 140 formed on the adhered surface of the substrate 130 from the conductive paste 124.

According to example embodiments, the conductive paste 124 may be formed on a base plate 110 with relatively low thermal deflection, for example, a glass substrate, to have a required pattern by a screen printing process. The substrate 130 may be disposed on the base plate 110, and the conductive paste 124 may have the required pattern which may be adhered to the substrate 130. The base plate 110 may be removed to form the wirings 140 having a required pattern.

Accordingly, the wirings 140 may be formed on the substrate 130 without performing an exposure process and an etching process. Because the wirings 140 are formed using the glass substrate having heat-resisting properties, thermal deflections of the substrate and dimension variations in manufacturing processes may be reduced or minimized.

Hereinafter, a method of manufacturing a tape package including the wiring substrate and a display device including the same will be described in detail.

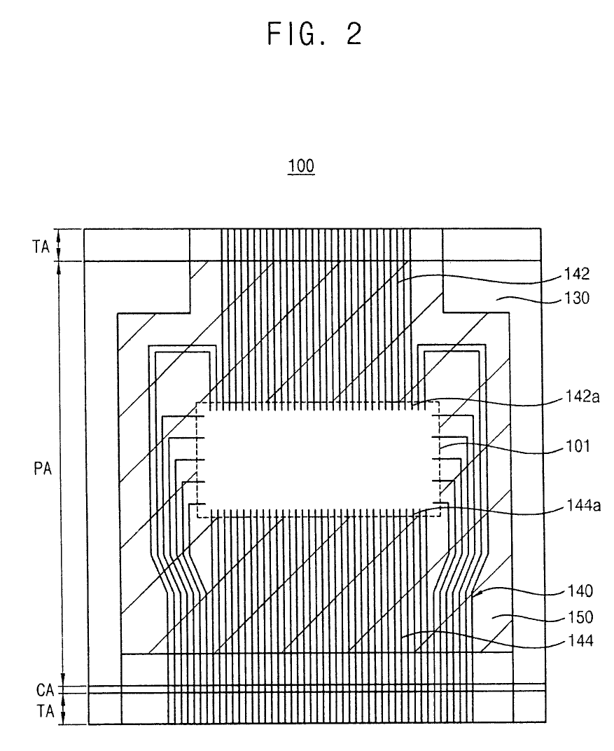

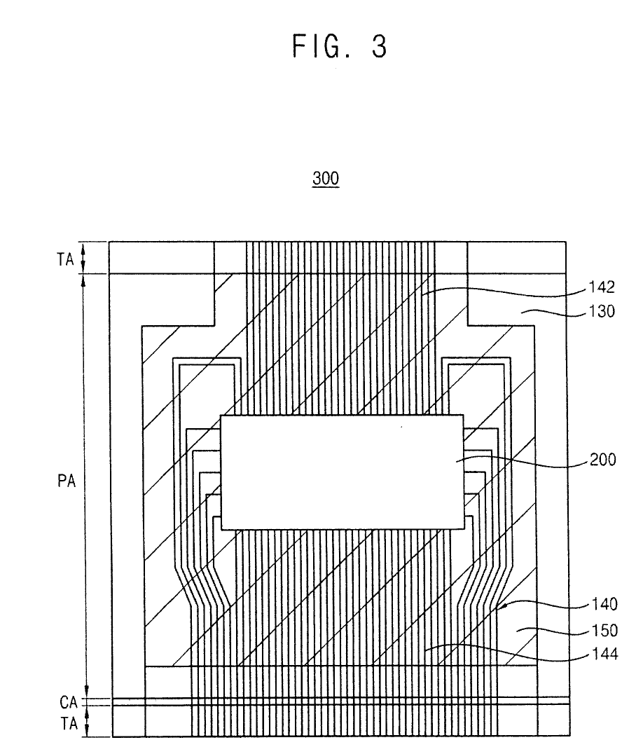

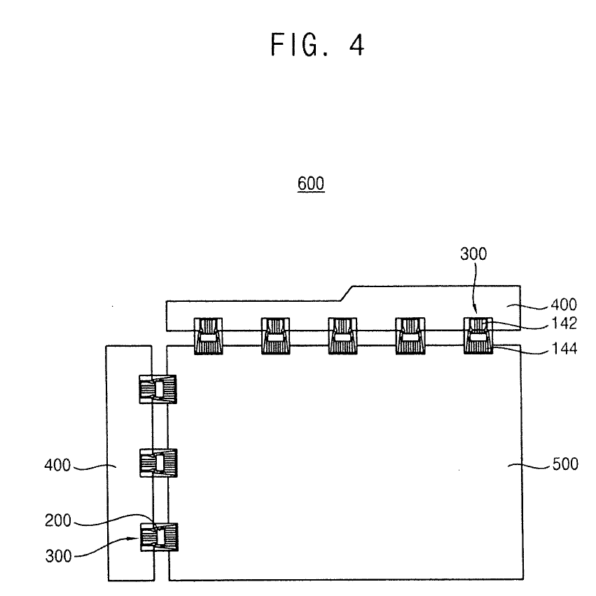

FIG. 2 is a plan view illustrating the wiring substrate 100 in FIG. 1E. FIG. 3 is a plan view illustrating a tape package 300 including a semiconductor chip 200 mounted on the wiring substrate 100 in FIG. 2. FIG. 4 is a plan view illustrating a display device 600 including the tape package 300 in FIG. 3.

Referring to FIG. 2, in example embodiments, a chip-mounted region 101, where a semiconductor chip may be mounted, may be provided in the wiring substrate 100. For example, the wiring substrate 100 may include a package region PA where a semiconductor chip may be mounted, an input/output test pad region TA provided on both sides of the package region PA, and a cutting region CA for separating the package region PA from the input/output test pad region TA.

The wirings 140 may be formed extending from the chip-mounted region 101. The wirings 140 may include input wirings 142 and output wirings 144. The input wiring 142 may be configured to connect to an input pad of a semiconductor chip. The output wiring 142 may be configured to connect to an output pad of a semiconductor chip. The input and output wirings 142 and 144 may include connection end portions 142a and 144a to be connected to the input and output pads of a semiconductor chip.

In example embodiments, after the wirings 140 are formed on the substrate 130, the input and output wirings 142 and 144 may be coated with an insulation member 150. The insulation member 150 may be coated to cover portions of the wirings 140 except the connection end portions 142a and 144a. For example, the insulation member 150 may include solder resist.

Referring to FIG. 3, a semiconductor chip 200 is mounted on the chip-mounted region 101 (see FIG. 2) of the wiring substrate 100 to form a tape package 300. The terminal pads (not shown) of the semiconductor chip 200 may be adhered to the connection end portions 142a and 144a of the wirings 140 via bumps interposing therebetween. A plastic resin may be injected to a bonded region of the wiring substrate 100 and the semiconductor chip 200. For example, the plastic resin may be injected to the bonded region of the semiconductor chip 200 through an underfill process.

Referring to FIG. 4, a first end portion of the tape package 300 may be combined with a printed circuit board (PCB) 400 and a second end portion of the tape package 300 may be combined with a display panel 500, to complete a display device 600.

After the semiconductor chip 200 is mounted on the wiring substrate 100, both edge side portions of the wiring substrate 100 except the package region PA may be removed. The input wirings 142 of the wirings 140 of the tape package 300 may be electrically connected to the PCB 400 and the output wirings 144 of the wirings 140 of the tape package 300 may be electrically connected to the display panel 500. The display device 500 may be completed by conventional processes for a flat-panel display (FPD) device.

For example, the display panel 500 may include a plurality of gate lines, a plurality of data lines and a plurality of pixels. The pixels may be formed on each intersection of the gate lines and the data lines. The pixel may include a thin-film transistor (TFT) having a gate electrode connected to the gate line and a source electrode connected to the data line.

The semiconductor chip 200 mounted on the tape package 300 may include driving circuits for driving the display panel 500. For example, the semiconductor chip 200 of the tape package 300 that combines with a first side of the display panel 500 may include a gate driver for driving the gate lines of the display panel 500. The semiconductor chip 200 of the tape package 300 that combines with a second side substantially perpendicular to the first side of the display panel 500 may include a data driver for driving the data lines of the display panel 500.

The PCB 400 may be electrically connected to the input wiring 142 of the tape package 300. For example, the PCB 400 may include a timing controller (not illustrated) and a power supply (not illustrated). The timing controller may control a driving timing of the gate driver and the data driver. The power supply may provide power required for the driving circuits of the display panel 500 and the semiconductor chip 200 that is mounted on the tape package 300.

As mentioned above, in a method of manufacturing a wiring substrate 100 in accordance with example embodiments, the conductive paste 124 may be formed on the base plate 110 with relatively low thermal deflection, for example, a glass substrate, to have a required pattern by a screen printing process. The substrate 130 may be disposed on the base plate 110 and the conductive paste 124 having the required pattern may be adhered to the substrate 130. The base plate 110 may be removed to form the wirings 140 having a required pattern.

Accordingly, the wirings 140 may be formed on the substrate 130 without performing an exposure process and an etching process. Because the wirings 140 are formed using the glass substrate having heat-resisting properties by simplified processes, thermal deflections of the substrate and dimension variations in manufacturing processes may be reduced or minimized.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of example embodiments and is not to be construed as limited to the specific example embodiments disclosed, and that modifications to example embodiments are intended to be included within the scope of the appended claims.

What is claimed is:

1. A method of manufacturing a wiring substrate, comprising:
placing a screen on a base plate, the screen having openings for forming wirings;
coating a conductive paste in the openings of the screen;
placing a substrate on the screen;
hardening the conductive paste to adhere the conductive paste to the substrate; and
removing the base plate and the screen from the substrate to expose wirings on the substrate.

2. The method of claim 1, further comprising:
forming an adhesive layer on the conductive paste.

3. The method of claim 2, wherein the adhesive layer comprises chromium (Cr).

4. The method of claim 2, wherein the adhesive layer has a root-mean-square (RMS) roughness greater than a RMS roughness of the conductive paste.

5. The method of claim 1, wherein hardening the conductive paste comprises heating the base plate.

6. The method of claim 1, wherein the base plate comprises a glass substrate, and hardening the conductive paste comprises irradiating light onto the glass substrate.

7. The method of claim 1, wherein the substrate comprises polyimide.

8. The method of claim 1, wherein the base plate is a glass substrate.

9. The method of claim 1, wherein the screen comprises one of glass and silicon.

10. A method of manufacturing a tape package, comprising:
manufacturing a wiring substrate according to claim 1; and
mounting a semiconductor chip on the wiring substrate.

11. The method of claim 10, further comprising:
forming an adhesive layer on the conductive paste.

12. The method of claim 11, wherein the adhesive layer comprises chromium (Cr).

13. The method of claim 11, wherein the adhesive layer has a root-mean-square (RMS) roughness greater than a RMS roughness of the conductive paste.

14. The method of claim 10, wherein mounting the semiconductor chip on the wiring substrate comprises adhering terminal pads of the semiconductor chip to connection end portions of the wirings via bumps therebetween.

15. The method of claim 10, further comprising:
injecting a plastic resin to a bonded region of the wiring substrate and the semiconductor chip.

16. The method of claim 10, wherein the semiconductor chip comprises driving circuits for driving a display panel.

17. A method of manufacturing a display device, comprising:
manufacturing a wiring substrate according to claim 1;
mounting a semiconductor chip on the wiring substrate to form a tape package;
combining a first end portion of the tape package with a PCB; and
combining a second end portion of the tape package with a display panel.

18. The method of claim 17, wherein combining the first end portion of the tape package with the PCB comprises electrically connecting input wirings of the wirings of the wiring substrate to the PCB.

19. The method of claim 17, wherein combining the second end portion of the tape package with the display panel comprises electrically connecting output wirings of the wirings of the wiring substrate to the display panel.

20. The method of claim 17, wherein the semiconductor chip comprises one of a gate driver and a data driver.
